(19) United States
(12) Patent Application Publication
(10) Pub. No.: US 2026/0165164 A1
(43) Pub. Date: Jun. 11, 2026

(54) PACKAGE BASE SUBSTRATES AND SEMICONDUCTOR PACKAGES HAVING THE SAME

(71) Applicant: Samsung Electronics Co., Ltd., Suwon-si (KR)

(72) Inventor: Yongsung Park, Suwon-si (KR)

(21) Appl. No.: 19/293,484

(22) Filed: Aug. 7, 2025

(30) Foreign Application Priority Data
Dec. 9, 2024 (KR) 10-2024-0181961

(51) Int. Cl. H01L 23/498; H01L 21/48

(52) U.S. Cl. CPC H10W 70/65; H10W 70/093; H10W 70/685; H10W 90/701

(57) ABSTRACT

A package base substrate includes a substrate base, a plurality of lower connection pads at a lower surface of the substrate base, a plurality of lower wiring patterns at the lower surface of the substrate base, each of the plurality of lower wiring patterns connected to a respective lower connection pad, a lower protective layer at the lower surface of the substrate base and covering the plurality of lower wiring patterns and a portion of each lower connection pad of the plurality of lower connection pads, and a reinforcement structure on a lower connection pad of the plurality of lower connection pads, the reinforcement structure extending from the lower connection pad toward an upper surface of the substrate base, wherein a first portion of the reinforcement structure overlaps the lower connection pad, and a second portion of the reinforcement structure does not overlap the lower connection pad.

### CROSS-REFERENCE TO RELATED APPLICATION

This application is based on and claims priority under 35 U.S.C. § 119 to Korean Patent Application No. 10-2024-0181961, filed on Dec. 9, 2024, in the Korean Intellectual Property Office, the disclosure of which is incorporated by reference herein in its entirety.

### BACKGROUND

The inventive concept relates to a package base substrate and a semiconductor package including the package base substrate, and more particularly, to a package base substrate, to which one or more semiconductor chips are attached, and a semiconductor package including the package base substrate.

Semiconductor packages may include semiconductor chips mounted on upper surfaces of package base substrates, molding layers surrounding the semiconductor chips, and solder balls arranged on lower surfaces of the package base substrates. A semiconductor package may be electrically connected to a board substrate by using a solder ball disposed on the lower surface of a package base substrate. Therefore, it is important to ensure the reliability of a lower connection pad through which a solder ball is connected to the package base substrate in the semiconductor package.

### SUMMARY

The inventive concept provides a semiconductor package having improved reliability by preventing the occurrence of defects in a package base substrate. Accordingly, the inventive concept provides a package base substrate capable of ensuring reliability and a semiconductor package including the package base substrate.

Also, the objects of the inventive concept are not limited to the aforementioned object, but other objects not described herein will be clearly understood by those skilled in the art from the following description.

According to an aspect of the inventive concept, a package base substrate comprises a substrate base, a plurality of lower connection pads at a lower surface of the substrate base, a plurality of lower wiring patterns at the lower surface of the substrate base, each of the plurality of lower wiring patterns connected to a respective lower connection pad of the plurality of lower connection pads, a lower protective layer at the lower surface of the substrate base and covering the plurality of lower wiring patterns and a portion of each lower connection pad of the plurality of lower connection pads, and a reinforcement structure on a lower connection pad of the plurality of lower connection pads, the reinforcement structure extending from the lower connection pad toward an upper surface of the substrate base, wherein a first portion of the reinforcement structure overlaps the lower connection pad in a vertical direction, and a second portion of the reinforcement structure does not overlap the lower connection pad in the vertical direction.

According to another aspect of the inventive concept, a semiconductor package comprises a package base substrate, and a semiconductor chip connected to the package base substrate, the package base substrate comprising: a substrate base comprising at least one base layer; a plurality of upper connection pads on an upper surface of the substrate base and electrically connected to the semiconductor chip; a plurality of lower connection pads at a lower surface of the substrate base, each of the plurality of lower connection pads attached to a respective external connection terminal of a plurality of external connection terminals; a plurality of lower wiring patterns at the lower surface of the substrate base, each of the plurality of lower wiring patterns connected to a respective lower connection pad of the plurality of lower connection pads; a lower protective layer covering the lower surface of the substrate base, wherein the lower protective layer does not cover at least a portion of each lower connection pad of the plurality of lower connection pads; and a reinforcement structure on a lower connection pad of the plurality of lower connection pads, the reinforcement structure extending from the lower connection pad toward the upper surface of the substrate base, wherein the reinforcement structure comprises: a first portion overlapping the lower connection pad in a vertical direction, and a second portion overlapping a lower wiring pattern of the plurality of lower wiring patterns in the vertical direction.

According to another aspect of the inventive concept, a semiconductor package comprises a package base substrate, and a semiconductor chip mounted on the package base substrate, wherein the package base substrate comprises: a substrate base comprising at least one base layer; a plurality of upper connection pads on an upper surface of the substrate base and electrically connected to the semiconductor chip; a plurality of lower connection pads at a lower surface of the substrate base, each of the plurality of lower connection pads attached to a respective external connection terminal of a plurality of external connection terminals; a plurality of lower wiring patterns at the lower surface of the substrate base, each of the plurality of lower wiring patterns connected to a respective lower connection pad of the plurality of lower connection pads, a lower protective layer covering the lower surface of the substrate base, wherein the lower protective layer does not cover at least a portion of each lower connection pad of the plurality of lower connection pads; and a reinforcement structure on a lower connection pad of the plurality of lower connection pads, the reinforcement structure extending from the lower connection pad toward the upper surface of the substrate base, and wherein a portion of the reinforcement structure does not overlap the lower connection pad in a vertical direction.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is an enlarged cross-sectional view illustrating a region of a lower connection pad of the package base substrate according to an embodiment;

FIG. 3 is a plan view schematically showing the arrangement relationship between a lower connection pad, a lower wiring pattern, and a reinforcement structure, according to an embodiment;

FIG. 4 is a plan view schematically showing the arrangement relationship between a lower connection pad, a lower wiring pattern, and a reinforcement structure, according to an embodiment;

FIG. 5 is a plan view schematically showing the arrangement relationship between a lower connection pad, a lower wiring pattern, and a reinforcement structure, according to an embodiment;

FIG. 6 is a plan view schematically showing the arrangement relationship between a lower connection pad, a lower wiring pattern, and a reinforcement structure, according to an embodiment;

FIG. 7 is an enlarged cross-sectional view illustrating a region of a lower connection pad of a package base substrate according to an embodiment;

FIGS. 8 to 11 are cross-sectional views showing a method of manufacturing a lower connection pad, a lower wiring pattern, and a reinforcement structure, according to an embodiment;

FIGS. 12 to 15 are cross-sectional views showing a method of manufacturing a lower connection pad, a lower wiring pattern, and a reinforcement structure, according to an embodiment;

FIG. 16 is a block diagram showing the configuration of a semiconductor package according to an embodiment; and

FIG. 17 is a block diagram schematically showing the configuration of a semiconductor package according to an embodiment.

### DETAILED DESCRIPTION OF THE EMBODIMENTS

Hereinafter, embodiments are described in detail with reference to the accompanying drawings. The same reference numerals are given to the same elements in the drawings, and repeated descriptions thereof are omitted. In the following drawings, the thickness and size of each layer are exaggerated for convenience and clarity of description, and may be slightly different from the actual shape and proportions thereof.

As used herein, terms representing spatial relationships, such as “bottom,” “below,” “lower,” “top,” and “upper,” are intended only to describe relative positional relationships between elements or patterns shown in the drawings, and are used for ease of understanding only and do not limit the inventive concept at all. The terms for the relative positions in space are intended to encompass changes due to the orientation of a semiconductor device in addition to the directions shown in the drawings. That is, the semiconductor device may be oriented in various directions when used (or manufactured), and the terms for the positions used herein are easily understood by a person skilled in the art.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

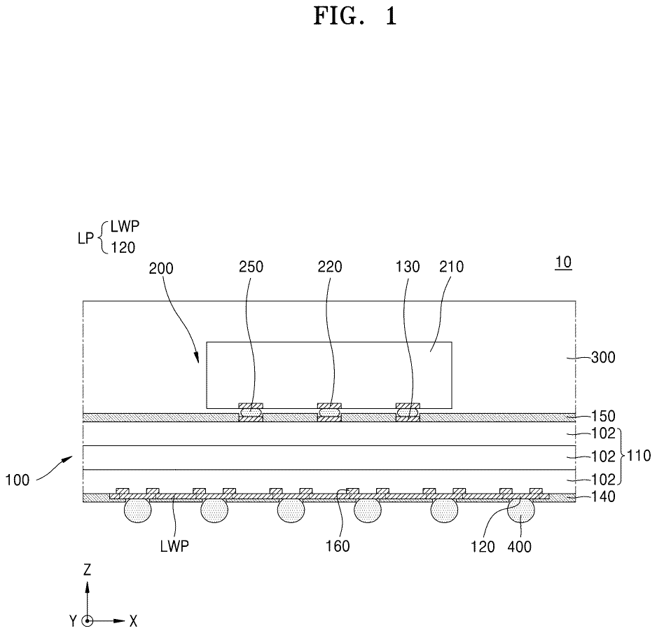

FIG. 1 is a cross-sectional view illustrating a semiconductor package 10 according to an embodiment.

Referring to FIG. 1, the semiconductor package 10 includes a package base substrate 100 and a semiconductor chip 200. The package base substrate 100 may include, for example, a printed circuit board (PCB). For example, the package base substrate 100 may include a double-sided PCB. The package base substrate 100 may include a substrate base 110, which is formed by stacking at least one base layer 102, a plurality of lower connection pads 120, and a plurality of upper connection pads 130. The plurality of lower connection pads 120 are positioned at the lower surface of the substrate base 110, and the plurality of upper connection pads 130 are positioned on the upper surface of the substrate base 110.

The lower surface of the substrate base 110 and the upper surface of the substrate base 110 may be spaced apart from each other in a vertical direction (e.g., a Z direction). As used herein, when a component comprises two opposing surfaces (e.g., a lower surface and an upper surface), the surface closer to an external connection terminal 400 may be referred to as the lower surface, and the surface opposite to the lower surface may be referred to as the upper surface of the component. A distance between the external connection terminal 400 and the lower surface may therefore be less than a distance between the external connection terminal 400 and the upper surface in the vertical direction.

As used herein, a horizontal direction (e.g., an X direction and/or a Y direction) may be defined as a direction parallel to a main surface of the package base substrate 100 and parallel to a lower surface and an upper surface of a component, and the vertical direction (e.g., the Z direction) may be defined as a direction perpendicular to the horizontal direction (e.g., the X direction and/or the Y direction).

The package base substrate 100 may include a multi-layer PCB. When the package base substrate 100 includes the multi-layer PCB, wiring layers may be on the lower surface, the upper surface, and the inside of the package base substrate 100.

In some embodiments, a lower protective layer 140 and an upper protective layer 150 may be on the lower surface and the upper surface of the package base substrate 100, respectively. In some embodiments, the lower protective layer 140 may cover side surfaces of the lower connection pads and may at least partially cover lower surfaces of the plurality of lower connection pads 120. At least a portion of each lower connection pad 120 of the plurality of lower connection pads 120 may not be covered by the lower protective layer 140, such that a portion of each of the lower surfaces of the plurality of lower connection pads 120 may be exposed and not covered by the lower protective layer 140. For example, a portion of each of the lower surfaces of the plurality of lower connection pads 120 may be exposed with respect to the lower protective layer 140. At least a portion of each upper connection pad 130 of the plurality of upper connection pads 130 may not be covered by the upper protective layer 150, such that upper surfaces of the plurality of upper connection pads 130 may be exposed and not covered by the upper protective layer 150. For example, a portion of each of the upper surfaces of the plurality of upper connection pads 130 may be exposed with respect to the upper protective layer 150.

In some embodiments, edge-adjacent regions of the plurality of lower connection pads 120 and the plurality of upper connection pads 130 may be covered by the lower protective layer 140 and the upper protective layer 150, respectively, while the remaining regions thereof may be partially uncovered and exposed.

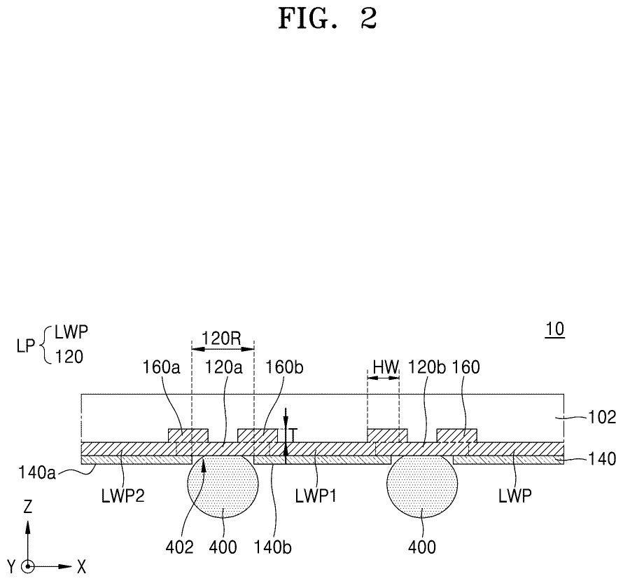

The lower protective layer 140 may have a plurality of openings, and the plurality of lower connection pads 120 may be at least partially exposed via the plurality of openings. For example, with reference to one of the lower connection pads 120, the region of the lower connection pad 120 that is exposed via the opening (e.g., and is not covered by the lower protective layer 140) may represent a terminal contact 120R (see FIG. 2) that is in contact with the external connection terminal 400. For example, one of the external connection terminals 400 can extend through one of the openings of the lower protective layer 140 to connect the external connection terminal 400 to an exposed lower connection pad 120. A plurality of external connection terminals 400 may be respectively attached to the plurality of lower connection pads 120, for example, with each opening in the lower protective layer 140 providing for a connection between one external connection terminal 400 and one lower connection pad 120. The plurality of external connection terminals 400 may electrically connect the semiconductor package 10 to an electronic device.

The external connection terminal 400 may be electrically connected to a wiring line inside the package base substrate 100 via the lower connection pad 120. For example, the external connection terminal 400 may include a solder ball and/or a bump. In some embodiments, the external connection terminal 400 may include a reinforced solder ball having enhanced durability. For example, the external connection terminal 400 may include bismuth (Bi), zinc (Zn), palladium (Pd), antimony (Sb), and/or indium (In) and thus have improved durability. In some embodiments, the external connection terminal 400 may comprise a cross-sectional size (e.g., a diameter when the external connection terminal 400 is circular) that is within a range from 150 micrometers to 760 micrometers. When the durability of the external connection terminal 400 increases, the stress generated in the semiconductor package 10 may be transferred to the lower connection pads 120. Therefore, reinforcement structures 160 may be disposed on the lower connection pads 120.

In some embodiments, the package base substrate 100 may not include the lower protective layer 140 and the upper protective layer 150. In some embodiments, the plurality of lower connection pads 120 and the plurality of upper connection pads 130 are buried or embedded in the substrate base 110, and thus, the lower surfaces of the plurality of lower connection pads 120 and the upper surfaces of the plurality of upper connection pads 130 may be co-planar with the lower surface and the upper surface of the substrate base 110, respectively.

In some embodiments, the base layer 102 may include at least one material selected from a group consisting of phenolic resin, epoxy resin, and polyimide. For example, the base layer 102 may include at least one material selected from a group consisting of flame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The package base substrate 100 may include an inner wiring pattern (not shown) located between the base layers 102 and a conductive via passing through at least one base layer 102, such that the inner wiring pattern and the conductive via may electrically connect the plurality of lower connection pads 120 to the plurality of upper connection pads 130. In some embodiments, a lower region of the package base substrate 100 may further include a lower wiring pattern LWP that is electrically and/or physically connected to the plurality of lower connection pads 120. The lower wiring pattern LWP may be completely covered by the lower protective layer 140. In some embodiments, an upper region of the package base substrate 100 may further include an upper wiring pattern that is electrically and/or physically connected to the plurality of upper connection pads 130.

The plurality of lower connection pads 120, the plurality of upper connection pads 130, the inner wiring pattern, and the lower wiring pattern LWP may be formed of, for example, an electrolytically deposited (ED) copper foil, a rolled-annealed (RA) copper foil, a stainless-steel foil, an aluminum foil, ultra-thin copper foils, sputtered copper, copper alloys, etc. The conductive via may be formed of, for example, copper, nickel, stainless-steel, or beryllium copper. The lower wiring pattern LWP and/or the inner wires may constitute a wiring layer. The lower wiring pattern LWP and the inner wiring pattern may be referred to as a wiring line. The wiring line may include a signal wire and a power wire.

The semiconductor chip 200 may be mounted on the package base substrate 100. The semiconductor chip 200 may include a semiconductor substrate 210. The semiconductor substrate 210 may include, for example, silicon (Si). The semiconductor substrate 210 may include semiconductor elements, such as germanium (Ge), or compound semiconductors, such as silicon carbide (SiC), gallium arsenide (GaAs), indium arsenide (InAs), and indium phosphide (InP). The semiconductor substrate 210 may have a silicon on insulator (SOI) structure. For example, the semiconductor substrate 210 may include a buried oxide (BOX) layer. The semiconductor substrate 210 may include a conductive region, for example, a well doped with impurities. The semiconductor substrate 210 may have various device isolation structures, such as a shallow trench isolation (STI) structure. The semiconductor substrate 210 may have an active surface and an inactive surface opposite to the active surface.

A semiconductor device, including a plurality of other types of individual devices, may be formed on the active surface of the semiconductor chip 200. The plurality of individual devices may include other microelectronic devices, for example, metal-oxide-semiconductor field effect transistors (MOSFET), such as complementary metal-oxide-semiconductor (CMOS) transistors, system large scale integration (LSI), image sensors, such as CMOS imaging sensors (CIS), micro-electro-mechanical systems (MEMS), active devices, passive devices, etc. The plurality of individual devices may be electrically connected to the conductive region of the semiconductor substrate 210. The semiconductor device may further include a conductive wire or a conductive plug, which electrically connects at least two of the plurality of individual devices to each other or electrically connects the plurality of individual devices to the conductive region of the semiconductor substrate 210. In some embodiments, the plurality of individual devices may be electrically separated from other adjacent individual devices by an insulating layer.

The semiconductor chip 200 may include, for example, a memory semiconductor chip. The memory semiconductor chip may include, for example, non-volatile memory semiconductor chips, such as flash memory, phase-change random-access memory (PRAM), magnetoresistive random-access memory (MRAM), ferroelectric random-access memory (FeRAM), and resistive random-access memory (RRAM). The flash memory may include, for example, a vertical NOT-AND (V-NAND) flash memory. In some embodiments, the semiconductor chip 200 may include volatile memory semiconductor chips, such as dynamic random-access memory (DRAM) and static random-access memory (SRAM).

The semiconductor chip 200 may include, for example, a power management integrated circuit (PMIC) and/or a logic semiconductor chip. The logic semiconductor chip may include, for example, a microprocessor, such as a central processing unit (CPU), a graphics processing unit (GPU), or an application processor (AP), an analog device, or a digital signal processor.

The semiconductor chip 200 may include a plurality of chip pads 220 on the active surface thereof. For example, the semiconductor chip 200 may be mounted on the package base substrate 100 such that the active surface of the semiconductor chip 200 faces downwards, i.e., toward the package base substrate 100.

A connection member 250 may be located between the upper connection pad 130 of the package base substrate 100 and the plurality of chip pads 220 of the semiconductor chip 200. For example, the connection member 250 may include a conductive pillar and/or a solder bump. The semiconductor chip 200 may be electrically connected to the package base substrate 100 via the connection member 250.

While FIG. 1 illustrates one possible configuration of electrically connecting the package base substrate 100 to the semiconductor chip 200, the package base substrate 100 may be electrically connected to the semiconductor chip 200 in other ways. For example, the package base substrate 100 may be electrically connected to the semiconductor chip 200 by a wire bonding method.

A molding layer 300 covering the upper surface of the package base substrate 100 and surrounding the semiconductor chip 200 may be disposed on the package base substrate 100. The molding layer 300 may include, for example, a silicone-based material, a thermosetting material, a thermoplastic material, or an ultraviolet (UV) treated material. The molding layer 300 may include polymer such as resin, and may include, for example, an epoxy molding compound (EMC).

FIG. 2 is an enlarged cross-sectional view illustrating a region of the lower connection pad 120 of the package base substrate 100 according to an embodiment. A description is given below with reference to FIG. 2.

Referring to FIG. 2, the base layer 102 of the substrate base 110, lower connection pads 120a, 120b, and the external connection terminal 400 are shown. In addition, as described above, the plurality of lower connection pads 120a, 120b, which are spaced apart from each other in the horizontal direction (e.g., the X direction and/or the Y direction), may be physically and/or electrically connected to each other by the lower wiring pattern LWP. The lower connection pads 120a, 120b and/or the lower wiring pattern LWP may each include an ED copper foil, an RA copper foil, a stainless-steel foil, an aluminum foil, an ultra-thin copper foil, a sputtered copper, a copper alloy, etc. For example, the lower connection pads 120a, 120b and the lower wiring pattern LWP may include the same material and form an integrated single body. Alternatively, the lower connection pads 120a, 120b and the lower wiring pattern LWP may be formed of different materials and may be electrically-connected to each other as shown in FIG. 2.

The lower wiring pattern LWP may be completely covered by the lower protective layer 140. For example, the lower surfaces of the lower wiring pattern LWP may be covered by the lower protective layer 140. In some embodiments, side surfaces of the lower wiring pattern LWP may be covered by the lower protective layer 140. With reference to FIG. 2, the lower wiring pattern LWP can comprise a first lower wiring pattern LWP1 and a second lower wiring pattern LWP2, while the lower connection pads 120 can comprise a first lower connection pad 120a and a second lower connection pad 120b. One end of the first lower wiring pattern LWP1 may be in contact with the first lower connection pad 120a, and an opposing end of the first lower wiring pattern LWP1 may be in contact with the second lower connection pad 120b. The first lower connection pad 120a and the second lower connection pad 120b are not limited to the positions illustrated in FIG. 2, and may represent different locations for lower connection pads 120, which are spaced apart from each other in the horizontal direction (e.g., the X direction and/or the Y direction).

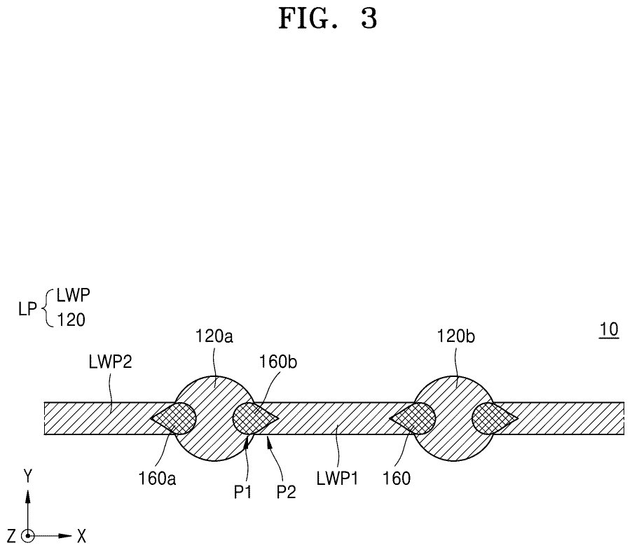

The semiconductor package 10 may comprise a plurality of reinforcement structures 160 (e.g., which may also be referred to as reinforcement protrusions 160) that may partially cover the lower connection pads 120 and/or the lower wiring pattern LWP. For purposes of description, the following description is directed toward a first reinforcement structure 160a and a second reinforcement structure 160b, but, unless otherwise noted, the other reinforcement structures 160 may be similar or identical in structure, function, and positioning relative to a respective lower connection pad 120 and a lower wiring pattern LWP. The plurality of reinforcement structures 160 may extend in the vertical direction (e.g., the Z direction) toward the center of the package base substrate 100 and may be disposed on the lower connection pads 120. For example, the plurality of reinforcement structures 160 may extend from the lower connection pads 120 toward an upper surface of the substrate base. The plurality of reinforcement structures 160 may disperse thermal and/or mechanical stress transmitted to the lower connection pads 120 and/or the external connection terminals 400. In addition, the plurality of reinforcement structures 160 may include a support via and/or a dummy via that is not used as a signal path. The plurality of reinforcement structures may each have a pillar shape. The cross-sectional shape of the reinforcement structure 160 is described in detail with reference to FIGS. 3 to 6.

As illustrated in FIG. 2, the plurality of reinforcement structures 160 may comprise the first reinforcement structure 160a, the second reinforcement structure 160b, and additional reinforcement structures that may be similar or identical to the first reinforcement structure 160a and the second reinforcement structure 160b. The first reinforcement structure 160a and the second reinforcement structure 160b may be spaced apart from each other to define a space or opening between the first reinforcement structure 160a and the second reinforcement structure 160b. The first reinforcement structure 160a may overlap the first lower connection pad 120a and the second lower wiring pattern LWP2. For example, the first reinforcement structure 160a may comprise a first portion and a second portion, wherein the first portion overlaps at least a portion of the first lower connection pad 120a in the vertical direction, and the second portion overlaps at least a portion of the second lower wiring pattern LWP2. The first portion of the first reinforcement structure 160a does not overlap the second lower wiring pattern LWP2, and the second portion of the first reinforcement structure 160a does not overlap the first lower connection pad 120a. By overlapping, a line extending in the vertical direction (e.g., the Z direction) may intersect the overlapping structures, for example, with a line intersecting the first portion of the first reinforcement structure 160a and the first lower connection pad 120a. Likewise, a different line extending in the vertical direction intersects the second portion of the first reinforcement structure 160a and the second lower wiring pattern LWP2. Accordingly, the first reinforcement structure 160a may overlap the junction at which an end of the first lower connection pad 120a connects to (e.g., for example, contacts) an end of the second lower wiring pattern LWP2.

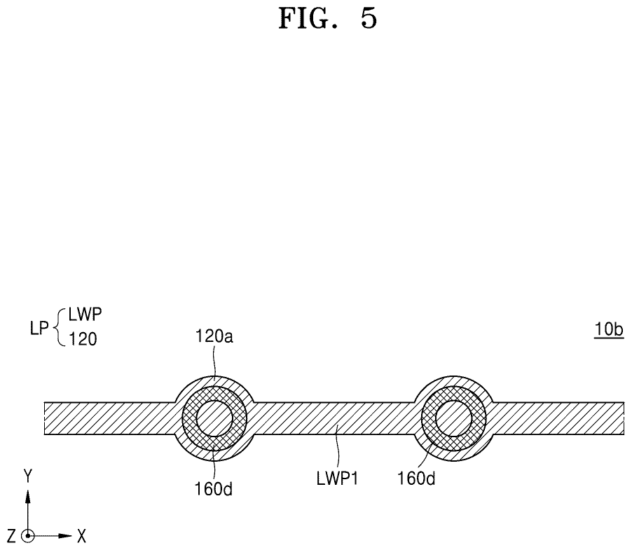

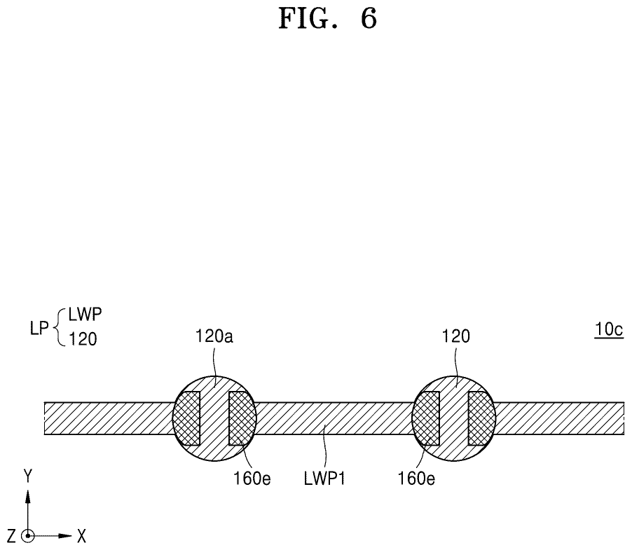

Accordingly, at least a portion (e.g., the first portion) of the first reinforcement structure 160a may overlap the first lower connection pad 120a in the vertical direction (the Z direction). In some embodiments, at least a portion (e.g., the second portion) of the first reinforcement structure 160a may not overlap the first lower connection pad 120a in the vertical direction (the Z direction). That is, at least a portion (e.g., the second portion) of the first reinforcement structure 160a may be spaced apart from the first lower connection pad 120a in the horizontal direction (the X direction and/or the Y direction). While FIG. 2 illustrates the reinforcement structures 160 partially overlapping the lower connection pads 120, this configuration is not intended to be limiting, and in some embodiments, all of the reinforcement structures 160 may overlap the lower connection pads 120 in the vertical direction (the Z direction) while not overlapping any of the lower wiring patterns LWP (e.g., illustrated in FIGS. 5-6). For example, the entirety of one reinforcement structure 160 (e.g., a first reinforcement structure) may overlap some, or all, of one of the lower connection pads 120 (e.g., a first lower connection pad), and the entirety of another reinforcement structure 160 (e.g., a second reinforcement structure) may overlap some, or all, of another one of the lower connection pads 120 (e.g., a second lower connection pad), etc.

In some embodiments, at least a portion of the first reinforcement structure 160a may overlap the terminal contact 120R of the first lower connection pad 120a in the vertical direction (the Z direction), and at least one other portion (e.g., a remaining portion) of the first reinforcement structure 160a may not overlap the terminal contact 120R of the first lower connection pad 120a in the vertical direction (the Z direction). That is, the remaining portion of the first reinforcement structure 160a may be spaced apart from the terminal contact 120R of the first lower connection pad 120a in the horizontal direction (the X direction and/or the Y direction). In a plan view, the terminal contact 120R of the first lower connection pad 120a may include a region in which the first lower connection pad 120a does not overlap the lower protective layer 140. Rather, the lower protective layer 140 may comprise a first protective layer portion 140a and a second protective layer portion 140b that are spaced apart from each other to define an opening within which one of the external connection terminals 400 extends. The opening between the adjacent lower protective layer portions 140a, 140b provides access to the terminal contact 120R. That is, a portion of the first lower connection pad 120a, which is exposed through the opening in the lower protective layer 140 between the adjacent lower protective layer portions 140a, 140b, may include the terminal contact 120R. In some embodiments, at least a portion of the first reinforcement structure 160a may overlap the lower protective layer 140 in the vertical direction (the Z direction), and at least another portion of the first reinforcement structure 160a may not overlap the lower protective layer 140 in the vertical direction (the Z direction). For example, a portion of the first reinforcement structure 160a may overlap the opening between the adjacent lower protective layer portions 140a, 140b and, as such, may not overlap any of the lower protective layer 140, while a remaining portion of the first reinforcement structure 160a may overlap the first protective layer portion 140a. Accordingly, the first reinforcement structure 160a may overlap an end of the first protective layer portion 140a that borders the opening between the adjacent lower protective layer portions 140a, 140b.

In some embodiments, the first reinforcement structure 160a may overlap the first lower connection pad 120a and/or the second lower wiring pattern LWP2 in the vertical direction (the Z direction). For convenience of description, the lower connection pad 120 and the lower wiring pattern LWP may together be referred to as a lower pattern LP. The reinforcement structures 160 may overlap the lower pattern LP in the vertical direction (the Z direction). In some embodiments, the lower surfaces of the reinforcement structures 160 may be directly connected to (e.g., may contact) the lower pattern LP, such that by being directly connected, the reinforcement structures 160 and the lower pattern LP may be either a single, unitary structure, or separate, non-unitary structures. In some embodiments, each reinforcement structure 160 in its entirety overlaps the lower pattern LP in the vertical direction. In some embodiments, the first reinforcement structure 160a may overlap a boundary location 402 at which the external connection terminal 400 is attached to a lower surface of the first lower connection pad 120a. The boundary location 402 is a location on the lower surface of the first lower connection pad 120a at which the external connection terminal 400 is attached to the first lower connection pad 120a, with the boundary location 402 being the outermost boundary of this connection. For example, on one side (e.g., the left side in FIG. 2) of the boundary location 402 in the X-direction, the external connection terminal 400 is not in contact with the lower surface of the first lower connection pad 120a, and on an opposite side (e.g., the right side in FIG. 2) of the boundary location 402 in the X-direction, the external connection terminal 400 is in contact with the lower surface of the first lower connection pad 120a. To provide further structural integrity to the semiconductor package 10, the first reinforcement structure 160a can be positioned to overlap the boundary location 402, such that the first reinforcement structure 160a may at least partially overlap the external connection terminal 400.

Each of the reinforcement structures 160 may have a horizontal width HW in the horizontal direction (the X direction and/or the Y direction). The horizontal width HW of each of the reinforcement structures 160 may be in a range from 10 micrometers to 100 micrometers. In addition, the reinforcement structures 160 may each have a thickness T in the vertical direction (the Z direction). The thickness T of the reinforcement structures 160 may be 1 micrometer or more. In some embodiments, the thickness T of the reinforcement structures 160 may be in a range from 1 micrometer to 50 micrometers. In some embodiments, the thickness T of the reinforcement structures 160 may be in a range from 5 micrometer to 50 micrometers.

In a plan view, each of the reinforcement structures 160 may be located adjacent to outer regions of a corresponding lower connection pad 120. For example, the first reinforcement structure 160a may be located adjacent to, and overlapping, a first outer region or edge of the first lower connection pad 120a, while the second reinforcement structure 160b may be located adjacent to, and overlapping, an opposing second outer region or edge of the second lower connection pad 120b. In some embodiments, the lower connection pads 120 and the reinforcement structures 160 may be formed as a single, unitary body. For example, the first lower connection pad 120a, the first reinforcement structure 160a, and the second reinforcement structure 160b may be formed as a single, unitary body. In other embodiments, the lower connection pads 120 and the reinforcement structures 160 may be formed as separate, non-unitary, bodies. For example, the first lower connection pad 120a, the first reinforcement structure 160a, and the second reinforcement structure 160b may be separately formed and may comprise separate structures. A unitary structure, which may comprise a monolithic or integrated structure, may refer to a structure that is formed continuously without a grain boundary therebetween, while a non-unitary structure may be formed of different materials with a grain boundary between the two different materials. In some embodiments, the lower connection pads 120 and the reinforcement structures 160 may be formed of the same material. In other embodiments, the lower connection pads 120 and the reinforcement structures 160 may be formed of different materials.

For example, the lower connection pads 120 and/or the reinforcement structures 160 may be formed of metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or alloys thereof.

The reinforcement structures 160 may be formed on the lower connection pads 120, thereby preventing cracks from occurring between the lower connection pad 120 and the lower wiring pattern LWP. The reinforcement structures 160 may therefore be at a different level than the lower connection pads 120 and the lower wiring pattern LWP, and at a different level than the lower protective layer 140. For example, the reinforcement structures 160 may be at a higher level than the lower connection pads 120 and the lower wiring pattern LWP, which are at a higher level than the lower protective layer 140.

The package base substrate 100 according to the inventive concept may include the reinforcement structures 160 that extend in the vertical direction (the Z direction) from the lower connection pads 120 toward the center of a substrate. Accordingly, the thermal and/or mechanical stress of the lower connection pads 120 and/or the external connection terminals 400 may be effectively dispersed. Therefore, the structural reliability of the package base substrate 100 may improve. For example, by improving the structural reliability of the package base substrate 100, the reinforcement structures 160 may disperse thermal and/or mechanical stress, which reduces the likelihood of cracks developing through one or more of the lower connection pads 120, the lower wiring pattern LWP, and/or the external connection terminals 400.

While FIGS. 1 and 2 illustrate an example in which the reinforcement structures 160 are formed on the lower connection pads 120, the inventive concept is not limited thereto. For example, the semiconductor package 10 may further include a reinforcement structure that extends in the vertical direction (the Z direction) from the upper connection pad 130 toward the center of the package base substrate 100.

FIGS. 1 and 2 illustrate the lower connection pad 120 in contact with the external connection terminal 400, but the inventive concept is not limited thereto. For example, an additional under bump metallization (UBM) layer may be located between the lower connection pad 120 and the external connection terminal 400, such that the lower connection pad 120 may be electrically connected to the external connection terminal 400 while not being in contact with the external connection terminal 400.

FIG. 3 is a plan view schematically showing the arrangement between the lower connection pad 120, the lower wiring pattern LWP, and the reinforcement structure 160 of the semiconductor package 10, according to an embodiment. For convenience of description, the following description is focused on the first lower connection pad 120a, the first lower wiring pattern LWP1, the second lower wiring pattern LWP2, the first reinforcement structure 160a, and the second reinforcement structure 160b. However, the other lower connection pads 120, lower wiring patterns LWP, and reinforcement structures 160 may be similar or identical to those illustrated in FIG. 2. A description is given below with reference to FIGS. 1 to 3.

As shown in FIG. 3, the reinforcement structures 160a, 160b may have a teardrop shape when viewed from above in a plan view or Z-direction. Here, when the reinforcement structures 160a, 160b have a teardrop shape when viewed from above in a plan view, a first region of the reinforcement structures 160 is relatively wide and has a shape that is rounded with a smoothly changing curvature, and a second region of the reinforcement structure 160 has a shape that gradually decreases in width in a direction away from the first region and has a sharp end. With reference to the first reinforcement structure 160a, the first region of the first reinforcement structure 160a may at least partially overlap the first lower connection pad 120a. When measured along the Y-direction, the first region is wider than the second region, and the first region may comprise a radius of curvature. The second region of the first reinforcement structure 160a may at least partially overlap the second lower wiring pattern LWP2, and a line or axis that is parallel to the X-direction may pass through the first region and the second region. The second region may be tapered and may comprise a gradually decreasing width (e.g., with the width measured along the Y-direction) in a direction along the X-direction away from the first region. The second region may taper to a single, pointed end. Accordingly, the first reinforcement structure 160a may comprise a shape that overlaps the first lower connection pad 120a and the second lower wiring pattern LWP2, for example, by overlapping the junction at which the first lower connection pad 120a and the second lower wiring pattern LWP2 are connected.

At least a portion of the first reinforcement structure 160a may overlap the first lower connection pad 120a in the vertical direction (the Z direction), and at least a portion of the first reinforcement structure 160a may not overlap the first lower connection pad 120a in the vertical direction (the Z direction). In some embodiments, at least a portion of the first reinforcement structure 160a may be in contact with the first lower connection pad 120a. In some embodiments, at least a portion of the first reinforcement structure 160a may overlap the second lower wiring pattern LWP2 in the vertical direction (the Z direction). In some embodiments, at least a portion of the first reinforcement structure 160a may be directly connected to (e.g., in contact with) the second lower wiring pattern LWP2. In other embodiments, the portion of the first reinforcement structure 160a that overlaps the second lower wiring pattern LWP2 in the vertical direction (the Z direction) may not be in contact with the second lower wiring pattern LWP2 and may be spaced apart from the second lower wiring pattern LWP2 in the vertical direction (the Z direction), for example, with an intervening layer or material between the first reinforcement structure 160a and the second lower wiring pattern LWP2.

The second reinforcement structure 160b may be substantially identical in structure to the first reinforcement structure 160a, however, the second reinforcement structure 160b may be at a different location than the first reinforcement structure 160a. For example, as illustrated in FIG. 3, the second reinforcement structure 160b may include a first section P1 that overlaps the first lower connection pad 120a in the vertical direction (the Z direction) and a second section P2 that overlaps the first lower wiring pattern LWP1 in the vertical direction (the Z direction). The first section P1 and the second section P2 may be connected to each other, with the first section P1 comprising the rounded shape, and the second section P2 comprising the tapered shape. For example, a flat region of the first section P1 may be in contact with a flat region of the second section P2. The first section P1 and the second section P2 of the second reinforcement structure 160b are described separately for convenience of description, however, the second reinforcement structure 160b may be formed as a single, unitary body.

In some embodiments, the horizontal area of the first section P1 may be different than, for example, greater than, the horizontal area of the second section P2. In other embodiments, the horizontal area of the first section P1 may be equal to or less than the horizontal area of the second section P2. In some embodiments, the first section P1 may overlap the lower connection pad 120a while the second section P2 may overlap the first lower wiring pattern LWP1.

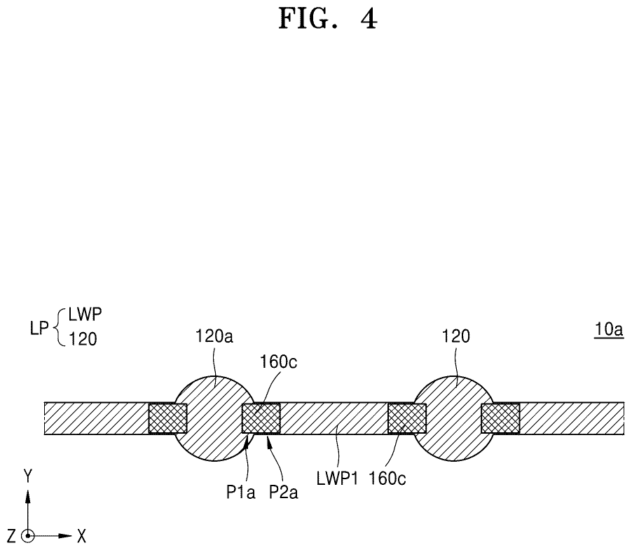

FIG. 4 is a plan view schematically showing the arrangement between the first lower connection pad 120a, the first lower wiring pattern LWP1, and a reinforcement structure 160c, according to an embodiment. A semiconductor package 10a of FIG. 4 may include the lower connection pads 120, the lower wiring patterns LWP, and the reinforcement structure 160c. For convenience of description, FIG. 4 focuses on the first lower connection pad 120a, the first lower wiring pattern LWP1, and the reinforcement structure 160c, however, the other lower connection pads 120, lower wiring patterns LWP, and reinforcement structures 160 may be similar or identical to those illustrated in FIG. 4. A description is given below with reference to FIGS. 1 to 4 together.

Referring to FIG. 4, the reinforcement structure 160c comprises a different shape than the reinforcement structures 160a, 160b illustrated in FIG. 3, and the reinforcement structure 160c may have a quadrangular shape as viewed from above in the Z-direction. A quadrangular, or quadrilateral shape is a shape that has four sides, which may be straight, and four angles. FIG. 4 illustrates one possible quadrangular shape, but the reinforcement structure 160c may comprise other quadrangular shapes, such as, for example, squares, rectangles, trapezoids, rhombuses, etc. However, the inventive concept is not limited to quadrangular shapes, and the reinforcement structure 160c may have other shapes. For example, the reinforcement structure 160c may have a circular, elliptical, polygonal, and/or irregular shape. The reinforcement structures 160 disclosed herein may have a regular polygon shape, wherein the angles are equal and the sides are equal. Alternatively, the reinforcement structures 160 may have an irregular polygon shape, wherein one or more of the sides are not equal and/or one or more of the angles are not equal. The reinforcement structures 160 may have a symmetrical shape with mirror-image halves when divided by a line of symmetry or may have an asymmetrical shape in which halves are not mirror images of one another. The irregular shapes may comprise, for example, the irregular polygon shape, the asymmetrical shape, etc.

A first section P1a of the reinforcement structure 160c may overlap the first lower connection pad 120a in the vertical direction (the Z direction) and a second section P2a of the reinforcement structure 160c may not overlap the first lower connection pad 120a in the vertical direction (the Z direction). In some embodiments, the second section P2a of the reinforcement structure 160c may overlap the first lower wiring pattern LWP1 in the vertical direction (the Z direction). In some embodiments, the second section P2a of the reinforcement structure 160c may be in contact with the first lower wiring pattern LWP1. In other embodiments, the second section P2a of the reinforcement structure 160c, which overlaps the first lower wiring pattern LWP1 in the vertical direction (the Z direction), may be spaced apart from the first lower wiring pattern LWP1 in the vertical direction (the Z direction), for example, with an intervening layer or material between the reinforcement structure 160c and the first lower wiring pattern LWP1. The overlapping position of the reinforcement structures 160c relative to the lower wiring patterns LWP, the lower connection pads 120, the lower protective layer 140, and the external connection terminal 400 may be the same as the overlapping position of the reinforcement structures 160 illustrated and described relative to FIG. 2.

FIG. 5 is a plan view schematically showing the arrangement between the first lower connection pad 120a, the first lower wiring pattern LWP1, and a reinforcement structure 160d, according to an embodiment. A semiconductor package 10b of FIG. 5 may include the lower connection pads 120, the lower wiring patterns LWP, and the reinforcement structure 160d. For convenience of description, FIG. 5 focuses on the first lower connection pad 120a, the first lower wiring pattern LWP1, and the reinforcement structure 160d, however, the other lower connection pads 120, lower wiring patterns LWP, and reinforcement structures 160 may be similar or identical to those illustrated in FIG. 5. A description is given below with reference to FIGS. 1 to 5 together.

Referring to FIG. 5, the reinforcement structure 160d comprises a different shape than the reinforcement structures 160a, 160b, 160c illustrated in FIGS. 3-4, and the reinforcement structure 160d may have a circular, or annular, ring shape as viewed from above in the Z-direction. When the reinforcement structure 160d has the circular, or annular, ring shape, the reinforcement structure 160d has a hollow space that is surrounded by a closed circular shape comprising an outer circumferential surface and an inner circumferential surface. However, the inventive concept is not limited to the shape of FIG. 5, and the reinforcement structure 160d may have other ring shapes. For example, the reinforcement structure 160d may have a non-circular ring shape, such as, for example, a quadrangular ring shape and/or a polygonal ring shape that are hollow in the center. In addition, FIG. 5 illustrates one possible size of the reinforcement structure 160d relative to a size of the first lower connection pad 120a, and other sizes are possible. For example, the reinforcement structure 160d can comprise a larger or smaller radial distance between the outer circumferential surface and the inner circumferential surface, and/or the reinforcement structure 160d may comprise a larger diameter (e.g., such that the outer circumferential surface may be in closer proximity to an outer region of the first lower connection pad 120a) or a smaller diameter.

The entirety of reinforcement structure 160d may overlap the first lower connection pad 120a in the vertical direction (the Z direction) such that an entirety of one of the reinforcement structures 160d overlaps the first lower connection pad 120a but does not overlap the first lower wiring pattern LWP1. In some embodiments, the reinforcement structure 160d may be spaced apart from the lower wiring pattern LWP in the horizontal direction (the X direction and/or the Y direction). Similar to the overlapping position illustrated and described relative to FIG. 2, the reinforcement structure 160d may overlap the external connection terminal 400 and the boundary location 402 at which the external connection terminal 400 is connected to the lower surface of the first lower connection pad 120a.

FIG. 6 is a plan view schematically showing the arrangement between the first lower connection pad 120a, the first lower wiring pattern LWP1, and a reinforcement structure 160e, according to an embodiment. A semiconductor package 10c of FIG. 6 may include the lower connection pads 120, the lower wiring patterns LWP, and the reinforcement structure 160e. For convenience of description, FIG. 6 focuses on the first lower connection pad 120a, the first lower wiring pattern LWP1, and the reinforcement structure 160e however, the other lower connection pads 120, lower wiring patterns LWP, and reinforcement structures 160 may be similar or identical to those illustrated in FIG. 6. A description is given below with reference to FIGS. 1 to 6 together.

Referring to FIG. 6, the reinforcement structure 160e comprises a different shape than the reinforcement structures 160a, 160b, 160c, 160d illustrated in FIGS. 3-5, and may include a first region having a curved shape including a semicircular shape and/or a circular arc shape as viewed from above in the Z-direction, and a second region having a quadrangular shape as viewed from above in the Z-direction. The first region and the second region are described separately for convenience of description, but the reinforcement structure 160e may be formed as a single, unitary body.

In some embodiments, the curved portion of the first region may have the same curvature as the outer surface of the first lower connection pad 120a. In other embodiments, the curved portion of the first region may have different curvature than the outer surface of the first lower connection pad 120a.

The entirety of reinforcement structure 160e may overlap the first lower connection pad 120a in the vertical direction (the Z direction) such that an entirety of one of the reinforcement structures 160e overlaps the first lower connection pad 120a but does not overlap the first lower wiring pattern LWP1. In some embodiments, the reinforcement structure 160e may be spaced apart from the lower wiring pattern LWP in the horizontal direction (the X direction and/or the Y direction). In other embodiments, at least a portion of the reinforcement structure 160e may not overlap the first lower connection pad 120a in the vertical direction (the Z direction). At least a portion of the reinforcement structure 160e may overlap the first lower wiring pattern LWP1 in the vertical direction (the Z direction). Similar to the overlapping position illustrated and described relative to FIG. 2, the reinforcement structure 160e may overlap the external connection terminal 400 and the boundary location 402 at which the external connection terminal 400 is connected to the lower surface of the first lower connection pad 120a.

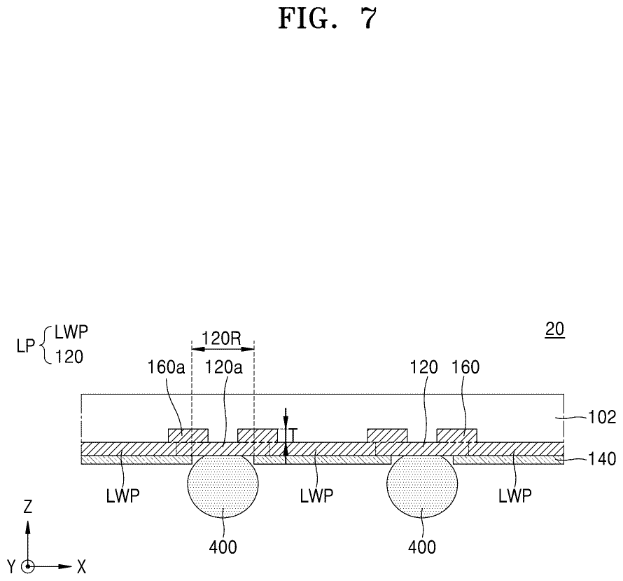

FIG. 7 is an enlarged cross-sectional view illustrating a region of a lower connection pad 120 of a package base substrate according to an embodiment. A description is given below with reference to FIGS. 1 and 2 together.

A semiconductor package 20 of FIG. 7 may include the lower connection pad 120, the lower wiring pattern LWP, and a reinforcement structure 160. The semiconductor package 20 of FIG. 7 may be similar to the semiconductor package 10 of FIGS. 1 and 2, except that the lower connection pad 120 and the reinforcement structure 160 in FIG. 7 are formed as separate bodies. Therefore, the description of FIG. 7 focuses on the lower connection pad 120 and the reinforcement structure 160.

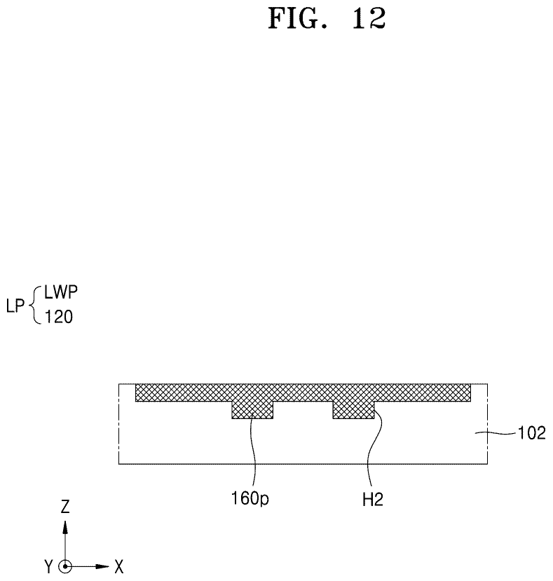

Referring to FIG. 7, the first lower connection pad 120a and the first reinforcement structure 160a may be formed as separate bodies. In some embodiments, the first lower connection pad 120a and the first reinforcement structure 160a may be formed of different materials. In other embodiments, the first lower connection pad 120a and the first reinforcement structure 160a may be formed of the same material. A method of forming the semiconductor package 20 of FIG. 7 is described in detail with reference to FIGS. 12 to 15.

FIG. 7 illustrates an example in which the reinforcement structures 160 are in contact with the lower pattern LP, but an insulating layer may be located between the reinforcement structures 160 and the lower pattern LP. The insulating layer provides electrical insulation between the reinforcement structures 160 and the lower pattern LP, which are formed as separate bodies, thereby increasing the reliability of a package base substrate 100a. For example, the insulating layer may include oxide and/or nitride.

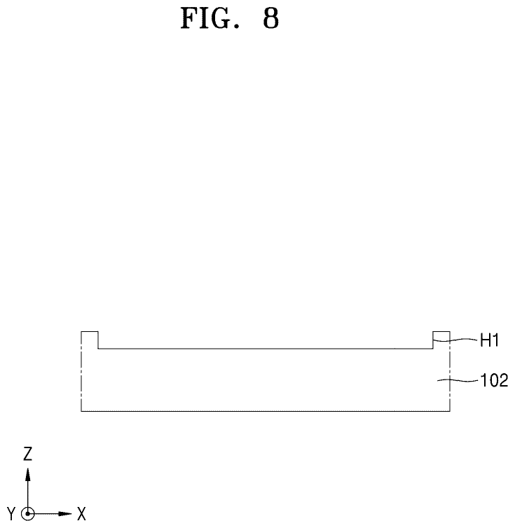

FIGS. 8 to 11 are cross-sectional views showing a method of manufacturing a lower connection pad, a lower wiring pattern, and a reinforcement structure, according to an embodiment. FIGS. 8 to 11 are diagrams illustrating a method of manufacturing the lower connection pads 120, the lower wiring pattern LWP, and the reinforcement structures 160 in the semiconductor package 10 of FIGS. 1 and 2. In FIGS. 8 to 11, one lower connection pad 120 and two lower wiring patterns LWP are shown as an example for convenience of description. A description is given below with reference to FIGS. 1 and 2 together.

Referring to FIG. 8, a first hole H1 may be formed in one surface of the base layer 102 to form the lower connection pad 120 and the lower wiring pattern LWP. For example, to form the first hole H1, a first mask pattern is formed on one surface of the base layer 102. Subsequently, the base layer 102 may be at least partially removed, thereby forming the first hole H1. However, the method of forming the first hole H1 is not limited thereto, and other methods may be used as well.

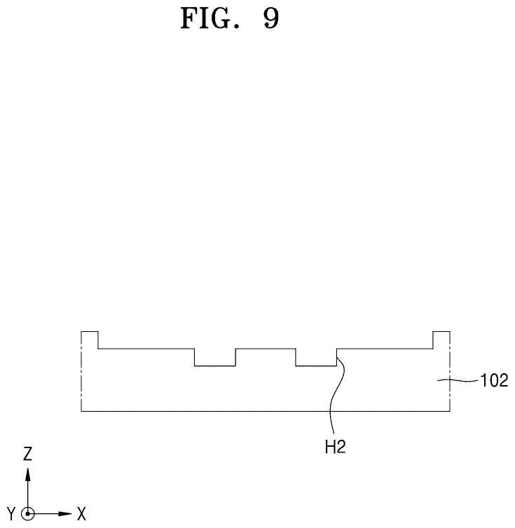

Referring to FIG. 9, a second hole H2 may be formed by removing at least a portion of the base layer 102, and the second hole H2 can facilitate the formation of the reinforcement structure 160. The lower surface of the second hole H2 may form a concave-convex shape. However, other shapes are possible, and the second hole H2 may be formed based on a desired shape of the reinforcement structure 160.

For example, to form the second hole H2, a second mask pattern is formed on one surface of the first hole H1. Subsequently, the base layer 102 is at least partially removed, thereby forming the second hole H2. However, the method of forming the second hole H2 is not limited thereto, and other methods may be used as well.

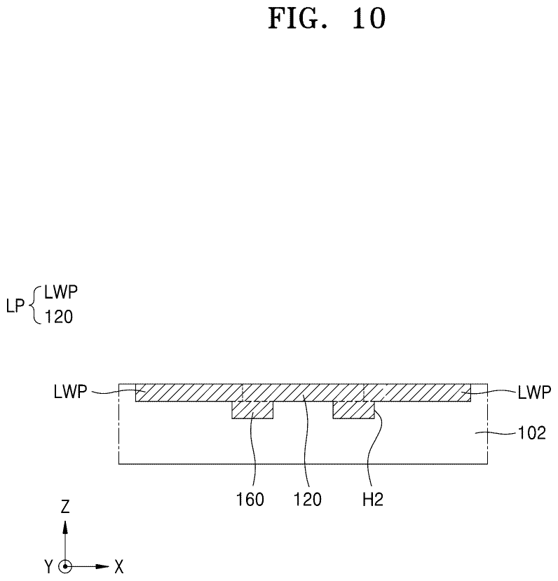

Referring to FIG. 10, the second mask pattern is removed, followed by a seed metal layer being formed in the second hole H2, and then a plating process is performed by using the seed metal layer. Accordingly, the lower connection pads 120 and the lower wiring pattern LWP may be formed in the first hole H1, and the reinforcement structures 160 may be formed in the second holes H2.

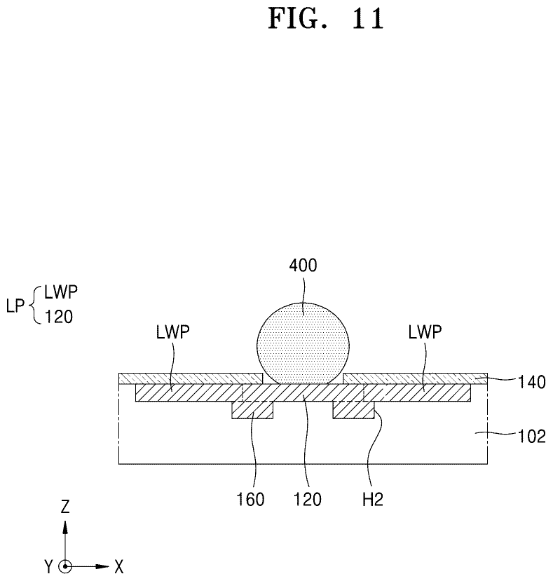

Referring to FIG. 11, the lower protective layer 140 may cover a portion of the lower surface of the substrate base 110 such that the lower connection pad 120 is at least partially exposed. The lower protective layer 140 may be formed by applying solder resist onto one surface of the base layer 102. Subsequently, the external connection terminal 400 may be attached to the lower connection pad 120. For example, the external connection terminal 400 may include a solder ball.

FIGS. 8 to 11 illustrate an example of forming the second hole H2 in a single base layer 102, but the inventive concept is not limited thereto. For example, the processes described with reference to FIGS. 8 to 11 may be performed on at least one base layer 102 among the plurality of base layers 102.

FIGS. 12 to 15 are cross-sectional views showing a method of manufacturing a lower connection pad, a lower wiring pattern, and a reinforcement structure, according to an embodiment. FIGS. 12 to 15 are diagrams illustrating a method of manufacturing the lower connection pad 120, the lower wiring pattern LWP, and the reinforcement structure 160 in the semiconductor package 20 of FIG. 7. In FIGS. 12 to 15, one lower connection pad 120 and two lower wiring patterns LWP are shown as an example for convenience of description. A description is given below with reference to FIGS. 1, 2, 8, and 9 together.

Referring to FIG. 12, a seed metal layer is formed on the lower surface of the second hole H2 in the structure of FIG. 9, and a plating process is performed by using the seed metal layer. Acco rdingly, a preliminary reinforcement structure 160p may be formed.

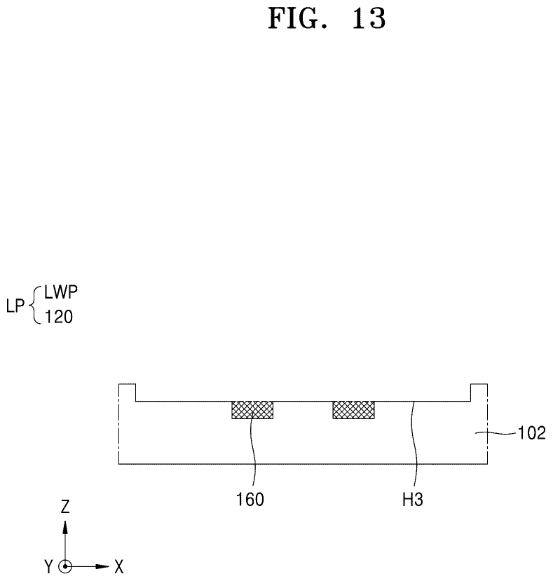

Referring to FIG. 13, the reinforcement structure 160 may be formed by removing at least a portion of the preliminary reinforcement structure 160p of FIG. 12. The preliminary reinforcement structure 160p (see FIG. 12) may be removed from a region in which the lower connection pad 120 and the lower wiring pattern LWP are to be formed. A third hole H3 may be defined by the substrate base 110 and the reinforcement structure 160. In some embodiments, the third hole H3 may be substantially the same as the first hole H1 (see FIG. 8). In other embodiments, the third hole H3 may be different from the first hole H1 (see FIG. 8).

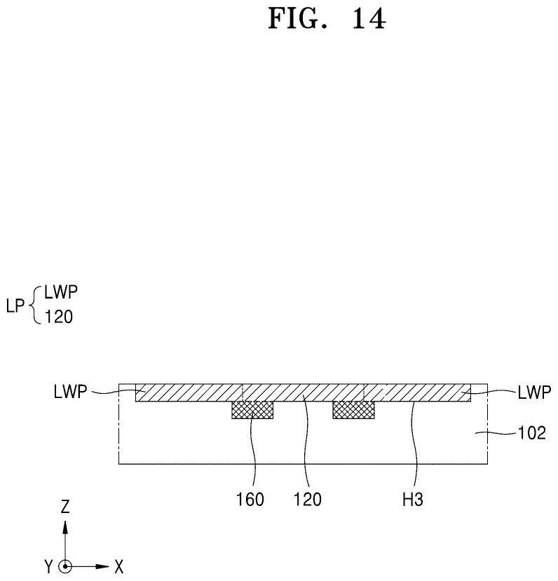

Referring to FIG. 14, a seed metal layer is formed in the third hole H3, and a plating process is performed by using the seed metal layer. Accordingly, the lower connection pad 120 and the lower wiring pattern LWP may be formed in the third hole H3.

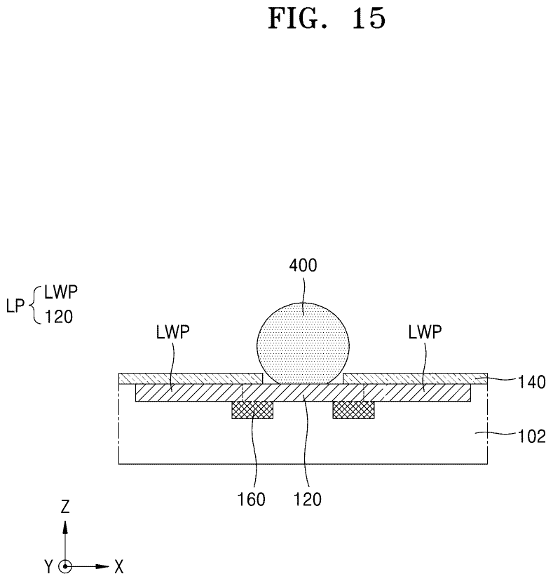

Referring to FIG. 15, the lower protective layer 140 may cover a portion of the lower surface of the substrate base 110 such that the lower connection pad 120 is at least partially exposed. The lower protective layer 140 may be formed by applying solder resist onto the lower surface of the substrate base 110. Subsequently, the external connection terminal 400 may be attached to the lower connection pad 120. For example, the external connection terminal 400 may include a solder ball.

FIG. 15 illustrates an example in which the reinforcement structure 160 is in contact with the lower pattern LP, but as described above, an insulating layer may be located between the reinforcement structure 160 and the lower pattern LP. First, the preliminary reinforcement structure 160p (see FIG. 12) is at least partially removed to form the reinforcement structure 160. Then, the insulating layer is formed on the reinforcement structure 160. Next, a seed metal layer is formed on the insulating layer. Subsequently, a plating process is performed by using the seed metal layer to form the lower connection pad 120 and the lower wiring pattern LWP.

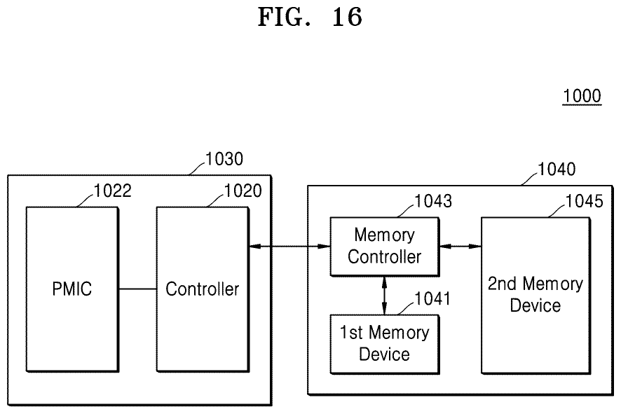

FIG. 16 is a block diagram showing the configuration of a semiconductor package 1000 according to an embodiment.

Referring to FIG. 16, the semiconductor package 1000 may correspond to one of the semiconductor packages 10, 10a, 10b, 10c, and 20 according to the inventive concept. The semiconductor package 1000 may include a controller chip 1020, a first memory chip 1041, a second memory chip 1045, and a memory controller 1043. The semiconductor package 1000 may further include a PMIC 1022 for supplying current of an operating voltage to each of the controller chip 1020, the first memory chip 1041, the second memory chip 1045, and the memory controller 1043. The operating voltages applied to respective components may be equal or different.

A lower package 1030 including the controller chip 1020 and the PMIC 1022 may include one of the semiconductor packages 10, 10a, 10b, 10c, and 20 according to the inventive concept as described above. An upper package 1040 including the first memory chip 1041, the second memory chip 1045, and the memory controller 1043 may include one of the semiconductor packages 10, 10a, 10b, 10c, and 20 according to the inventive concept as described above.

The semiconductor package 1000 may be provided inside a personal computer (PC) or a mobile device. The mobile device may be formed as a laptop computer, a mobile phone, a smart phone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile internet device (MID), a wearable computer, an internet of things (IoT) device, an internet of everything (IoE) device, or a drone.

The controller chip 1020 may control an operation of each of the first memory chip 1041, the second memory chip 1045, and the memory controller 1043. For example, the controller chip 1020 may be formed as an integrated circuit (IC), a system on chip (SoC), an AP, a mobile AP, a chip set, or a group of chips. The controller chip 1020 may include a CPU, a GPU, and/or a modem. In some embodiments, the controller chip 1020 may perform a function of the modem and a function of the AP.

The memory controller 1043 may control the second memory chip 1045 under control by the controller chip 1020. The first memory chip 1041 may be formed as a volatile memory device. The volatile memory device may be formed as RAM, DRAM, or SRAM, but the embodiment is not limited thereto. The second memory chip 1045 may be formed as a storage memory device. The storage memory device may be formed as a non-volatile memory device.

The storage memory device may be formed as a flash-based memory device, but the embodiment is not limited thereto. The second memory chip 1045 may be formed as a NAND-type flash memory device. The NAND-type flash memory device may include a 2-dimensional memory cell array or a 3-dimensional memory cell array. The 2-dimensional memory cell array or the 3-dimensional memory cell array may include a plurality of memory cells, and each of the plurality of memory cells may store one-bit information or at least two-bit information.

When the second memory chip 1045 is formed as the flash-based memory device, the memory controller 1043 may use (or support) a multimedia card (MMC) interface, an embedded MMC (eMMC) interface, or a universal flash storage (UFS) interface, but the embodiment is not limited thereto.

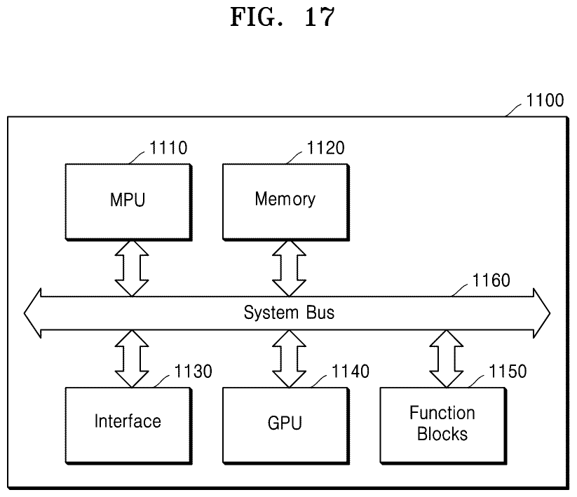

FIG. 17 is a block diagram schematically showing the configuration of a semiconductor package 1100 according to an embodiment.

Referring to FIG. 17, the semiconductor package 1100 may include a micro processing unit (MPU) 1110, memory 1120, an interface 1130, a GPU 1140, function blocks 1150, and a bus 1160 for establishing connections therebetween. The semiconductor package 1100 may include both the MPU 1110 and the GPU 1140 but may include only one of the MPU 1110 and the GPU 1140.

The MPU 1110 may include a core and an L2 cache. For example, the MPU 1110 may include multi-cores. In the multi-cores, individual cores may have equal or different performance. Further, in the multi-cores, the individual cores may be activated simultaneously or at different times. The memory 1120 may store the results of processing on the function blocks 1150 under control by the MPU 1110. For example, as contents stored in the L2 cache of the MPU 1110 are flushed, the contents may be stored in the memory 1120. The interface 1130 may interface with external devices. For example, the interface 1130 may interface with a camera, a liquid crystal display (LCD), and a speaker.

The GPU 1140 may perform graphics functions. For example, the GPU 1140 may perform video codec or may process 3D graphics. The function blocks 1150 may perform various functions. For example, when the semiconductor package 1100 includes an application processor (AP) used in the mobile device, some of the function blocks 1150 may perform communication functions.

The semiconductor package 1100 may include at least one of the semiconductor packages 10, 10a, 10b, 10c, and 20 according to the inventive concept as described above. The MPU 1110 and/or the GPU 1140 may include at least one of the semiconductor packages 10, 10a, 10b, 10c, and 20 according to the inventive concept as illustrated above. The memory 1120 may include at least one of the semiconductor packages 10, 10a, 10b, 10c, and 20 according to the inventive concept as illustrated above. The interface 1130 and the function blocks 1150 may include at least one of the semiconductor packages 10, 10a, 10b, 10c, and 20 according to the inventive concept as described above.

While the inventive concept has been particularly shown and described with reference to embodiments thereof, it will be understood that various changes in form and details may be made therein without departing from the spirit and scope of the following claims.

What is claimed is:

1. A package base substrate comprising:
a substrate base;
a plurality of lower connection pads at a lower surface of the substrate base;
a plurality of lower wiring patterns at the lower surface of the substrate base, each of the plurality of lower wiring patterns connected to a respective lower connection pad of the plurality of lower connection pads;
a lower protective layer at the lower surface of the substrate base and covering the plurality of lower wiring patterns and a portion of each lower connection pad of the plurality of lower connection pads; and
a reinforcement structure on a lower connection pad of the plurality of lower connection pads, the reinforcement structure extending from the lower connection pad toward an upper surface of the substrate base,
wherein a first portion of the reinforcement structure overlaps the lower connection pad in a vertical direction, and a second portion of the reinforcement structure does not overlap the lower connection pad in the vertical direction.

2. The package base substrate of claim 1, wherein, with respect to a plan view, the reinforcement structure comprises one of a teardrop shape, a polygonal shape, and an irregular shape.

3. The package base substrate of claim 1, wherein the second portion of the reinforcement structure overlaps a lower wiring pattern of the plurality of lower wiring patterns in the vertical direction, the lower wiring pattern connected to the lower connection pad.

4. The package base substrate of claim 1, wherein, with respect to a plan view, the reinforcement structure overlaps an outer region of the lower connection pad.

5. The package base substrate of claim 1, wherein the lower connection pad and the reinforcement structure are a single, unitary body.

6. The package base substrate of claim 1, wherein the lower connection pad and the reinforcement structure are separate, non-unitary, bodies.

7. The package base substrate of claim 1, wherein the reinforcement structure is formed of at least one of copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru).

8. A semiconductor package comprising:
a package base substrate; and
a semiconductor chip connected to the package base substrate,
the package base substrate comprising:
a substrate base comprising at least one base layer;
a plurality of upper connection pads on an upper surface of the substrate base and electrically connected to the semiconductor chip;
a plurality of lower connection pads at a lower surface of the substrate base, each of the plurality of lower connection pads attached to a respective external connection terminal of a plurality of external connection terminals;
a plurality of lower wiring patterns at the lower surface of the substrate base, each of the plurality of lower wiring patterns connected to a respective lower connection pad of the plurality of lower connection pads;
a lower protective layer covering the lower surface of the substrate base, wherein the lower protective layer does not cover at least a portion of each lower connection pad of the plurality of lower connection pads; and
a reinforcement structure on a lower connection pad of the plurality of lower connection pads, the reinforcement structure extending from the lower connection pad toward the upper surface of the substrate base,
wherein the reinforcement structure comprises:
a first portion overlapping the lower connection pad in a vertical direction; and
a second portion overlapping a lower wiring pattern of the plurality of lower wiring patterns in the vertical direction.

9. The semiconductor package of claim 8, wherein the plurality of lower connection pads each comprise a terminal contact to which a respective external connection terminal of the plurality of external connection terminals is attached, and
wherein the second portion of the reinforcement structure does not overlap the terminal contact in the vertical direction.

10. The semiconductor package of claim 8, wherein the plurality of lower connection pads and the plurality of lower wiring patterns form a lower pattern, and
the reinforcement structure is directly connected with the lower pattern.

11. The semiconductor package of claim 8, wherein the first portion of the reinforcement structure is directly connected with the lower connection pad, and
the second portion of the reinforcement structure is directly connected with the lower wiring pattern.

12. The semiconductor package of claim 8, wherein a horizontal area of the first portion of the reinforcement structure is different than a horizontal area of the second portion of the reinforcement structure.

13. The semiconductor package of claim 8, wherein the reinforcement structure and the plurality of lower connection pads comprise different materials.

14. The semiconductor package of claim 8, wherein the plurality of lower connection pads, the plurality of lower wiring patterns, and the reinforcement structure comprise the same material.

15. The semiconductor package of claim 8, wherein the reinforcement structure has a thickness in a range from 1 micrometer to 50 micrometers.

16. The semiconductor package of claim 8, wherein the reinforcement structure has a horizontal width in a range from 10 micrometers to 100 micrometers.

17. A semiconductor package comprising:
a package base substrate; and
a semiconductor chip mounted on the package base substrate,
wherein the package base substrate comprises:
a substrate base comprising at least one base layer;
a plurality of upper connection pads on an upper surface of the substrate base and electrically connected to the semiconductor chip;
a plurality of lower connection pads at a lower surface of the substrate base, each of the plurality of lower connection pads attached to a respective external connection terminal of a plurality of external connection terminals;
a plurality of lower wiring patterns at the lower surface of the substrate base, each of the plurality of lower wiring patterns connected to a respective lower connection pad of the plurality of lower connection pads;
a lower protective layer covering the lower surface of the substrate base, wherein the lower protective layer does not cover at least a portion of each lower connection pad of the plurality of lower connection pads; and
a reinforcement structure on a lower connection pad of the plurality of lower connection pads, the reinforcement structure extending from the lower connection pad toward the upper surface of the substrate base, and
wherein a portion of the reinforcement structure does not overlap the lower connection pad in a vertical direction.

18. The semiconductor package of claim 17, wherein the reinforcement structure at least partially overlaps the lower protective layer in the vertical direction.

19. The semiconductor package of claim 17, wherein a first portion of the reinforcement structure overlaps the lower connection pad of the plurality of lower connection pads in the vertical direction, and
the portion of the reinforcement structure that does not overlap the lower connection pad overlaps the lower wiring pattern of the plurality of lower wiring patterns in the vertical direction.

20. The semiconductor package of claim 19, wherein the portion of the reinforcement structure that does not overlap the lower connection pad is directly connected with the lower wiring pattern of the plurality of lower wiring patterns.

21. A semiconductor package comprising:
a package base substrate; and
a semiconductor chip connected to the package base substrate,
the package base substrate comprising:
a substrate base comprising at least one base layer;
a plurality of upper connection pads on an upper surface of the substrate base and electrically connected to the semiconductor chip;
a plurality of lower connection pads at a lower surface of the substrate base, each of the plurality of lower connection pads attached to a respective external connection terminal of a plurality of external connection terminals;
a plurality of lower wiring patterns at the lower surface of the substrate base, each of the plurality of lower wiring patterns connected to a respective lower connection pad of the plurality of lower connection pads;
a lower protective layer covering the lower surface of the substrate base, wherein the lower protective layer does not cover at least a portion of each lower connection pad of the plurality of lower connection pads; and
a reinforcement structure on a lower connection pad of the plurality of lower connection pads, the reinforcement structure extending from the lower connection pad toward the upper surface of the substrate base,
wherein the reinforcement structure overlaps, in a vertical direction, the lower connection pad and an external connection terminal of the plurality of external connection terminals.

22. The semiconductor package of claim 21, wherein the plurality of lower connection pads each comprise a terminal contact to which a respective external connection terminal of the plurality of external connection terminals is attached, and
wherein a portion of the reinforcement structure does not overlap the terminal contact in the vertical direction.

23. The semiconductor package of claim 21, wherein the plurality of lower connection pads and the plurality of lower wiring patterns form a lower pattern, and
the reinforcement structure is directly connected with the lower pattern.

24. The semiconductor package of claim 21, wherein a first portion of the reinforcement structure is directly connected with the lower connection pad, and
a second portion of the reinforcement structure is directly connected with the lower wiring pattern.

25. The semiconductor package of claim 24, wherein a horizontal area of the first portion of the reinforcement structure is different than a horizontal area of the second portion of the reinforcement structure.

26. The semiconductor package of claim 21, wherein the reinforcement structure and the plurality of lower connection pads comprise different materials.

27. The semiconductor package of claim 21, wherein the plurality of lower connection pads, the plurality of lower wiring patterns, and the reinforcement structure comprise the same material.

28. The semiconductor package of claim 21, wherein the reinforcement structure has a thickness in a range from 1 micrometer to 50 micrometers.

29. The semiconductor package of claim 21, wherein the reinforcement structure has a horizontal width in a range from 10 micrometers to 100 micrometers.
